(19) United States
(12) Patent Application Publication
(10) Pub. No.: US 2026/0114047 A1
(43) Pub. Date: Apr. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Na Hyeon CHA, Yongin-si (KR); Jun Hyun PARK, Yongin-si (KR); Sun Kwun SON, Yongin-si (KR); Cheol Gon LEE, Yongin-si (KR)

(73) Assignee: Samsung Display Co., LTD., Yongin-si (KR)

(21) Appl. No.: 19/283,742

(22) Filed: Jul. 29, 2025

(30) Foreign Application Priority Data
Oct. 22, 2024 (KR) 10-2024-0144827

(51) Int. Cl. H10D 86/40

(52) U.S. Cl. CPC H10D 86/441

(57) ABSTRACT

A display device includes a first-first gate line which includes a first-first-first gate line, a first-first-second gate line, and a first bridge line connecting the first-first-first gate line and the first-first-second gate line to each other and extends in a first direction, and a first-second gate line which includes a first-second-first gate line, a first-second-second gate line, and a second bridge line connecting the first-second-first gate line and the first-second-second gate line to each other, is spaced apart from the first-first gate line in a second direction intersecting the first direction, and extends in the first direction. A first contact hole connecting the first-first-first gate line and the first bridge line to each other is located between the first-first-second gate line and the first-second-second gate line.

### CROSS-REFERENCE TO RELATED APPLICATION(S)

This application claims priority to and the benefits of Korean Patent Application No. 10-2024-0144827 under 35 U.S.C. §119, filed on Oct. 22, 2024, in the Korean Intellectual Property Office (KIPO), the entire contents of which are incorporated herein by reference.

### BACKGROUND

### 1. Technical Field

Embodiments relate to a display device and an electronic device including the display device.

### 2. Description of the Related Art

With the development of information technologies, the importance of a display device which is a connection medium between a user and information increases.

### SUMMARY

Embodiments provide a display device and an electronic device including the display device, in which the spatiality of a double gate line is ensured.

However, the disclosure is not limited to those set forth herein. The disclosure will become more apparent to one of ordinary skill in the art to which the disclosure pertains by referencing the detailed description of the disclosure given below.

According to an embodiment, a display device may include a first-first gate line including a first-first-first gate line, a first-first-second gate line, and a first bridge line connecting the first-first-first gate line and the first-first-second gate line to each other, the first-first gate line extending in a first direction and a first-second gate line including a first-second-first gate line, a first-second-second gate line, and a second bridge line connecting the first-second-first gate line and the first-second-second gate line to each other, the first-second gate line being spaced apart from the first-first gate line in a second direction intersecting the first direction, the first-second gate line extending in the first direction. A first contact hole connecting the first-first-first gate line and the first bridge line to each other may be located between the first-first-second gate line and the first-second-second gate line.

A second contact hole connecting the first-second-first gate line and the second bridge line to each other may be spaced apart from the first contact hole in the first direction, and be located between the first-first-second gate line and the first-second-second gate line.

The first bridge line may extend to overlap at least a portion of the first-first-second gate line in a plan view.

The second bridge line may extend to overlap at least a portion of the first-second-second gate line in a plan view.

The display device may further include a first data line connected to a pair of first sub-pixels, a second data line connected to a pair of second sub-pixels, and a third data line connected to a pair of third sub-pixels.

The pair of first sub-pixels may be symmetrical to each other with respect to the first data line, the pair of second sub-pixels may be symmetrical to each other with respect to the second data line, and the pair of third sub-pixels may be symmetrical to each other with respect to the third data line.

The first-first gate line may be connected to one of the pair of first sub-pixels, one of the pair of second sub-pixels, and one of the pair of third sub-pixels. The first-second gate line may be connected to another one of the pair of first sub-pixels, another one of the pair of second sub-pixels, and another one of the pair of third sub-pixels.

The first contact hole may be located between the another one of the pair of first sub-pixels and the one of the pair of second sub-pixels.

The second contact hole may be located between the another one of the pair of second sub-pixels and the one of the pair of third sub-pixels.

The first contact hole and the second contact hole may be repeatedly arranged in each sub-pixel unit including the pair of first sub-pixels, the pair of second sub-pixels, and the pair of third sub-pixels.

According to an embodiment, a display device may include a first-first-first gate line and a first-second-first gate line, which are located on a substrate, a buffer layer covering the first-first-first gate line and the first-second-first gate line, a first gate insulating layer and a second gate insulating layer, which are located on the buffer layer, a first-first-second gate line located on the first gate insulating layer and a first-second-second gate line located on the second gate insulating layer, an interlayer insulating layer covering the first-first-second gate line and the first-second-second gate line, and a first bridge line and the second bridge line, which are located on the interlayer insulating layer. The first bridge line may be connected to the first-first-first gate line through a first contact hole, the second bridge line may be connected to the first-second-first gate line through a second contact hole, and the first contact hole may be located between the first-first-second gate line and the first-second-second gate line.

The second contact hole may be spaced apart from the first contact hole in a first direction, and be located between the first-first-second gate line and the first-second-second gate line.

The first bridge line may extend to overlap at least a portion of the first-first-second gate line in a plan view.

The second bridge line may extend to overlap at least a portion of the first-second-second gate line in a plan view.

The display device may further include a first data line connected to a pair of first sub-pixels, a second data line connected to a pair of second sub-pixels, and a third data line connected to a pair of third sub-pixels.

The pair of first sub-pixels may be symmetrical to each other with respect to the first data line, the pair of second sub-pixels may be symmetrical to each other with respect to the second data line, and the pair of third sub-pixels may be symmetrical to each other with respect to the third data line.

The first-first-first gate line and the first-first-second gate line may be connected to one of the pair of first sub-pixels, one of the pair of second sub-pixels, and one of the pair of third sub-pixels. The first-second-first gate line and the first second-second gate line may be connected to another one of the pair of first sub-pixels, another one of the pair of second sub-pixels, and another one of the pair of third sub-pixels.

The first contact hole may be located between the another one of the pair of first sub-pixels and the one of the pair of second sub-pixels.

The second contact hole may be located between the another one of the pair of second sub-pixels and the one of the pair of third sub-pixels.

The first contact hole and the second contact hole may be repeatedly arranged in each sub-pixel unit including the pair of first sub-pixels, the pair of second sub-pixels, and the pair of third sub-pixels.

According to an embodiment, an electronic device may include a display device and a processor that drives the display device. The display device may include a first-first gate line including a first-first-first gate line, a first-first-second gate line, and a first bridge line connecting the first-first-first gate line and the first-first-second gate line to each other, the first-first gate line extending in a first direction and a first-second gate line including a first-second-first gate line, a first-second-second gate line, and a second bridge line connecting the first-second-first gate line and the first-second-second gate line to each other, the first-second gate line being spaced apart from the first-first gate line in a second direction intersecting the first direction, the first-second gate line extending in the first direction. A first contact hole connecting the first-first-first gate line and the first bridge line to each other may be located between the first-first-second gate line and the first-second-second gate line.

A second contact hole connecting the first-second-first gate line and the second bridge line to each other may be spaced apart from the first contact hole in the first direction, and be located between the first-first-second gate line and the first-second-second gate line.

The first bridge line may extend to overlap at least a portion of the first-first-second gate line in a plan view.

The second bridge line may extend to overlap at least a portion of the first-second-second gate line in a plan view.

The display device may further include a first data line connected to a pair of first sub-pixels, a second data line connected to a pair of second sub-pixels, and a third data line connected to a pair of third sub-pixels.

The pair of first sub-pixels may be symmetrical to each other with respect to the first data line, the pair of second sub-pixels may be symmetrical to each other with respect to the second data line, and the pair of third sub-pixels may be symmetrical to each other with respect to the third data line.

The first-first gate line may be connected to one of the pair of first sub-pixels, one of the pair of second sub-pixels, and one of the pair of third sub-pixels. The first-second gate line may be connected to another one of the pair of first sub-pixels, another one of the pair of second sub-pixels, and another one of the pair of third sub-pixels.

The first contact hole may be located between the another one of the pair of first sub-pixels and the one of the pair of second sub-pixels.

The second contact hole may be located between the another one of the pair of second sub-pixels and the one of the pair of third sub-pixels.

The first contact hole and the second contact hole may be repeatedly arranged in each sub-pixel unit including the pair of first sub-pixels, the pair of second sub-pixels, and the pair of third sub-pixels.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram of a display device in accordance with an embodiment of the disclosure.

FIG. 2 is a schematic diagram of an equivalent circuit of a sub-pixel in accordance with an embodiment of the disclosure.

FIG. 3 is a schematic diagram schematically illustrating a connection relationship of sub-pixels, first gate lines, and data lines.

FIGS. 4 to 6 are plan views schematically illustrating layouts of the display device in accordance with an embodiment of the disclosure.

FIG. 7 is a schematic cross-sectional view taken along line I-I′ of FIG. 6 in accordance with an embodiment of the disclosure.

FIG. 8 is a schematic cross-sectional view taken along line II-II′ of FIG. 6 in accordance with an embodiment of the disclosure.

FIG. 9 is a schematic cross-sectional view taken along line III-III′ of FIG. 6 in accordance with an embodiment of the disclosure.

FIG. 10 is a schematic cross-sectional view taken along line IV-IV′ of FIG. 6 in accordance with an embodiment of the disclosure.

FIG. 11 is a schematic diagram schematically illustrating an arrangement of first and second contact holes in accordance with an embodiment of the disclosure.

FIG. 12 is a schematic diagram schematically illustrating an arrangement of first and second contact holes in accordance with an embodiment of the disclosure.

FIG. 13 is a plan view schematically illustrating a layout of the display device in accordance with an embodiment of the disclosure.

FIG. 14 is a schematic cross-sectional view taken along line V-V′ of FIG. 13.

FIG. 15 is a schematic cross-sectional view taken along line VI-VI′ of FIG. 13.

FIG. 16 is a schematic block diagram of an electronic device in accordance with an embodiment of the disclosure.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element.

In the specification and the claims, the phrase “at least one of” is intended to include the meaning of “at least one selected from the group of” for the purpose of its meaning and interpretation. For example, “at least one of A and B” may be understood to mean “A, B, or A and B.” Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ). In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanied drawings.

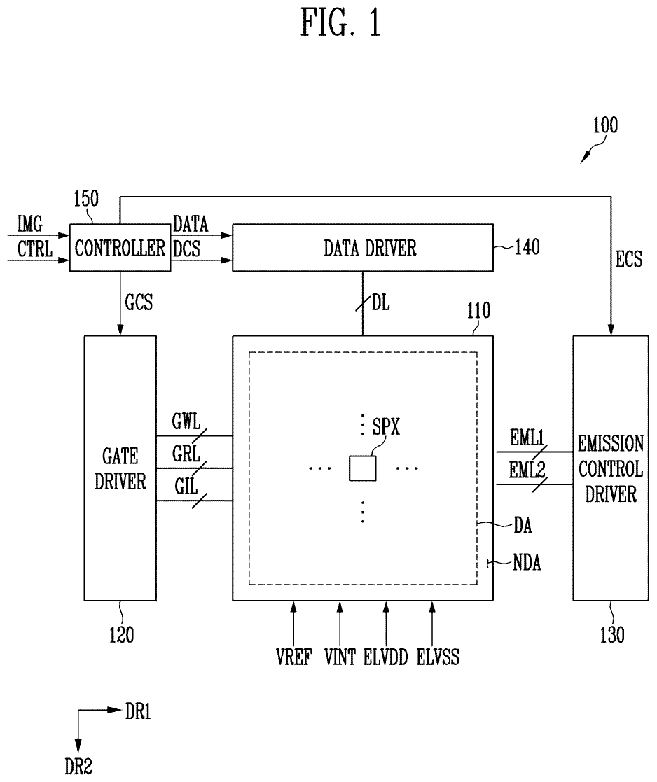

FIG. 1 is a schematic block diagram of a display device in accordance with an embodiment of the disclosure.

Referring to FIG. 1, a display device 100 may be a device which displays an image, and may be applied to electronic devices such as a mobile phone, a smart phone, a tablet PC, a smart watch, a watch phone, a mobile communication terminal, an electronic notebook, an electronic book, a Portable Multimedia Player (PMP), a navigation system, and an Ultra Mobile PC (UMPC). However, the disclosure is not necessarily limited thereto.

The display device 100 may include a display panel 110, a gate driver 120, an emission control driver 130, a data driver 140, and a controller 150.

The display panel 110 may include a display area DA and a non-display area NDA.

The display area DA may be an area in which an image is displayed, and may be a central area of the display panel 100. The display area DA may include sub-pixels SPX. The arrangement of the sub-pixels SPX is not particularly limited, and may be variously changed according to kinds of electronic devices to which the display device 100 is applied. The non-display area NDA may be an area other than the display area DA in the display panel 110. The non-display area NDA may include various lines, a pad portion, and the like.

A reference voltage VREF, an initialization voltage VINT, a first driving voltage ELVDD, and a second driving voltage ELVSS may be provided to the display panel 110. The reference voltage VREF, the initialization voltage VINT, the first driving voltage ELVDD, and the second driving voltage ELVSS may be applied to the sub-pixels SPX.

First gate line GWL may extend in a first direction DR1, and be spaced apart from each other in a second direction DR2. Second gate lines GRL may extend in the first direction DR1, and be spaced apart from each other in the second direction DR2. Third gate lines GIL may extend in the first direction DR1, and be spaced apart from each other in the second direction DR2. First emission control lines EML1 may extend in the first direction DR1, and be spaced apart from each other in the second direction DR2. Second emission control lines EML1 may extend in the first direction DR1, and be spaced apart from each other in the second direction DR2. Data lines DL may extend in the second direction DR2, and be spaced apart from each other in the first direction DR1.

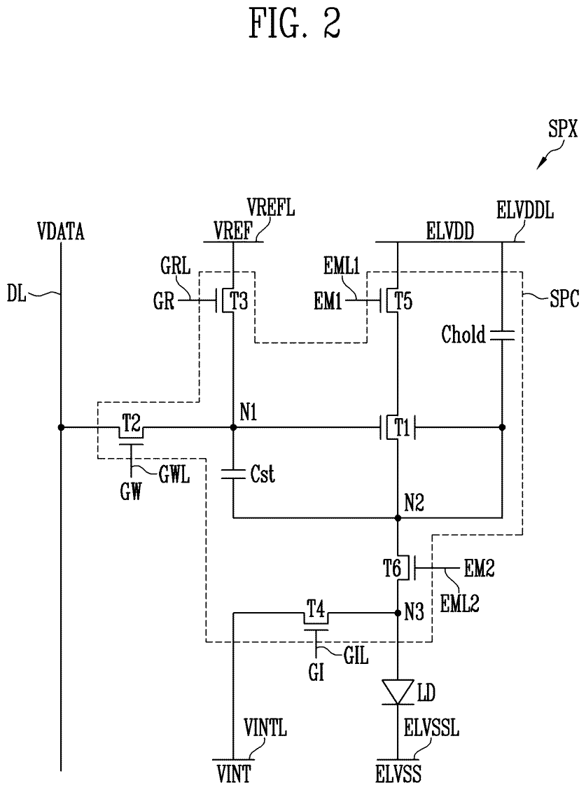

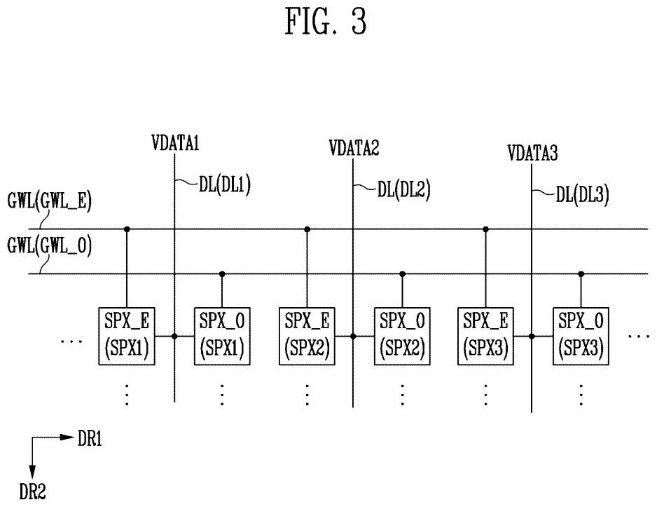

The gate driver 120 may be connected to the display panel 110 through the first gate lines GWL, the second gate lines GRL, and the third gate lines GIL. The first gate lines GWL may be connected to the sub-pixels SPX. A connection relationship between the first gate line GWL and the sub-pixels SPX will be described below with reference to FIG. 3. The second gate lines GRL may be connected to the sub-pixels SPX, respectively. The third gate lines GIL may be connected to the sub-pixels SPX, respectively. The gate driver 120 may sequentially apply first gate signals GW (see FIG. 2) to the first gate line GWL in unit of rows, based on a gate control signal GCS. The gate driver 120 may sequentially apply second gate signals GR (see FIG. 2) to the second gate lines GRL in units of rows, based on the gate control signal GCS. The gate driver 120 may sequentially apply third gate signals GI (see FIG. 2) to the third gate lines GIL in units of rows, based on the gate control signal GCS.

The emission control driver 130 may be connected to the display panel 110 through the first emission control lines EML1 and the second emission control lines EML2. The first emission control lines EML1 may be connected to the sub-pixels SPX, respectively. The second emission control lines EML2 may be connected to the sub-pixels SPX, respectively. The emission control driver 130 may apply first emission control signals EM1 (see FIG. 2) to the first emission control lines EML1, based on an emission control signal ECS. The emission control driver 130 may apply second emission control signals EM2 (see FIG. 2) to the second emission control lines EML2, based on the emission control signal ECS.

The data driver 140 may be connected to the display panel 110 through the data lines DL. The data lines DL may be connected to the sub-pixels SPX. A connection relationship between the data lines DL and the sub-pixels SPX will be described below with reference to FIG. 3. The data driver 140 may apply data signals VDATA (see FIG. 2) to the data lines DL, based on a data control signal DCS and image data DATA.

The controller 150 may control overall operations of the display device 100. The controller 150 may receive input image data IMG and a control signal CTRL from an outside (e.g., a processor). The controller 150 may provide the gate control signal GCS to the gate driver 120, based on the control signal CTRL. The controller 150 may provide the emission control signal ECS to the emission control driver 130, based on the control signal CTRL. The controller 150 may provide the data control signal DCS to the data driver 140, based on the control signal CTRL. Also, the controller 150 may generate image data DATA by converting the input image data IMG, and provide the image data DATA to the data driver 140.

FIG. 2 is a schematic diagram of an equivalent circuit of a sub-pixel in accordance with an embodiment of the disclosure.

Referring to FIG. 2, a sub-pixel SPX may include a sub-pixel circuit SPC and a light-emitting element LD.

The sub-pixel circuit SPC may include a first transistor T1, a second transistor T2, a third transistor T3, a fourth transistor T4, a fifth transistor T5, a sixth transistor T6, a first capacitor Cst, and a second capacitor Chold. Each of the first transistor T1, the second transistor T2, the third transistor T3, the fourth transistor T4, the fifth transistor T5, and the sixth transistor T6 may be an N-type oxide semiconductor transistor, but the disclosure is not necessarily limited thereto.

A first electrode of the first transistor T1 may be connected to a second node N2. A second electrode of the first transistor T1 may be connected to a first electrode of the fifth transistor T5. The first transistor T1 may be a double-gate transistor including a first gate electrode and a second gate electrode. The first gate electrode of the first transistor T1 may be connected to a first node N1. The second gate electrode of the first transistor T1 may be connected to the second node N2. In case that the second gate electrode of the first transistor T1 is connected to the second node N2, a gate-source voltage of the first transistor T1 and a driving current may be stably maintained. The first transistor T1 may control an amount of current supplied to the light-emitting element LD, corresponding to a voltage of the first node N1.

A first electrode of the second transistor T2 may be connected to the first node N1. A second electrode of the second transistor T2 may be connected to a data line DL. A gate electrode of the second transistor T2 may be connected to a first gate line GWL. In case that a first gate signal GW is supplied to the first gate line GWL, the second transistor T2 may be turned on, to electrically connect the data line Dl and the first node N1 to each other. Accordingly, a data signal VDATA may be supplied to the first node N1.

A first electrode of the third transistor T3 may be connected to the first node N1. A second electrode of the third transistor T3 may be connected to a reference line VREFL. A gate electrode of the third transistor may be connected to a second gate line GRL. In case that a second gate signal GR is supplied to the second gate line GRL, the third transistor T3 may be turned on, to electrically connect the reference line VREFL and the first node N1 to each other. Accordingly, the reference voltage VREF may be supplied to the first node N1.

A first electrode of the fourth transistor T4 may be connected to a third node N3. A second electrode of the fourth transistor T4 may be connected to an initialization line VINTL. A gate electrode of the fourth transistor T4 may be connected to a third gate line GIL. In case that a third gate signal GI is supplied to the third gate line GIL, the fourth transistor T4 may be turned on, to electrically connect the initialization line VINTL and the third node N3 to each other. Accordingly, the initialization voltage VINT may be supplied to the third node N3.

The first electrode of the fifth transistor T5 may be connected to the second electrode of the first transistor T1. A second electrode of the fifth transistor T5 may be connected to a first driving line ELVDDL to which the first driving voltage ELVDD is supplied. A gate electrode of the fifth transistor T5 may be connected to a first emission control line EML1. In case that a first emission control signal EM1 is supplied to the first emission control line EML1, the fifth transistor T5 may be turned off, and be turned on in case that the first emission control signal EM1 is not supplied to the first emission control line EML1. In case that the fifth transistor T5 is turned on, a current path may be formed, through which the driving current can flow through the light-emitting element LD.

A first electrode of the sixth transistor T6 may be connected to the third node N3. A second electrode of the sixth transistor T6 may be connected to the second node N2. A gate electrode of the sixth transistor T6 may be connected to a second emission control line EML2. In case that a second emission control signal EM2 is supplied to the second emission control line EML2, the sixth transistor T6 may be turned off, and be turned on in case that the second emission control signal EM2 is not supplied to the second emission control line EML2. In case that the sixth transistor T6 is turned on, a current path may be formed, through which the driving current can flow through the light-emitting element LD.

The first capacitor Cst may be connected between the first node N1 and the second node N2. The first capacitor Cst may store a voltage corresponding to the data signals VDATA.

The second capacitor Chold may be connected between the first driving line ELVDDL and the second node N2. The second capacitor Chold may stabilize a voltage of the second node N2.

The light-emitting element LD may be connected between the first driving line ELVDDL and a second driving line ELVSSL. For example, a first electrode (or anode) of the light-emitting element LD may be connected to the first driving line ELVDDL via the third node N3, the sixth transistor T6, the second node N2, the first transistor T1, and the fifth transistor T5. For example, a second electrode (or cathode) of the second electrode of the light-emitting element LD may be connected to the second driving line ELVSSL. The light-emitting element LD may generate light with a luminance corresponding to an amount of current supplied from the sub-pixel circuit SPC.

The light-emitting element LD may be an organic light-emitting diode, but the disclosure is not necessarily limited thereto. For example, the light-emitting element LD may be an inorganic light-emitting diode, such as a micro LED (light-emitting diode) or a quantum dot light-emitting diode, or an element configured with a combination of an organic material and an inorganic material.

FIG. 3 is a schematic diagram schematically illustrating a connection relationship of sub-pixels, first gate lines, and data lines.

Referring to FIG. 3, a pair of sub-pixels SPX_E and SPX_O may be commonly connected to a corresponding data line DL. For example, the pair of sub-pixels SPX_E and SPX_O may share the corresponding data line DL. For example, a pair of first sub-pixels SPX1 and SPX1 may be commonly connected to a first data line DL1 to which a first data signal VDATA1 is supplied. The pair of first sub-pixels SPX1 and SPX1 may emit light of a color (e.g., red light) corresponding to the first data signal VDATA1. For example, a pair of second sub-pixels SPX2 and SPX2 may be commonly connected to a second data line DL2 to which a second data signal VDATA2 is supplied. The pair of second sub-pixels SPX2 and SPX2 may emit light of a color (e.g., green light) corresponding to the second data signal VDATA2. For example, a pair of third sub-pixels SPX3 and SPX3 may be commonly connected to a third data line DL3 to which a third data signal VDATA3 is supplied. The pair of third sub-pixels SPX3 and SPX3 may emit light of a color (e.g., blue light) corresponding to the third data signal VDATA3. The first data line DL1, the second data line DL2, and the third data line DL3 may extend in the second direction DR2, and be spaced apart from each other in the first direction DR1.

The pair of sub-pixels SPX_E and SPX_O may be connected to first gate lines GWL, respectively. For example, one SPX_E of the pair of sub-pixels SPX_E and SPX_O may be connected to a (1-1)th gate line GWL_E, and another one SPX_O of the pair of sub-pixels SPX_E and SPX_O may be connected to a (1-2)th gate line GWL_O. The (1-1)th gate line GWL_E and the (1-2)th gate line GWL_O may extend in the first direction DR1, and be spaced apart from each other in the second direction DR2.

Accordingly, a data signal VDATA (see FIG. 2) may be individually supplied to a pair of sub-pixels SPX_E and SPX_O connected to a same data line DL. For example, in case that the first gate signal GW (see FIG. 2) is supplied to the (1-1)th gate line GWL_E, the first data signal VDATA1 may be supplied to the first sub-pixel SPX1 connected to the first data line DL1 and the (1-1)th gate line GWL_E, the second data signal VDATA2 may be supplied to the second sub-pixel SPX2 connected to the second data line DL2 and the (1-1)th gate line GWL_E, and the third data signal VDATA3 may be supplied to the third sub-pixel SPX3 connected to the third data line DL3 and the (1-1)th gate line GWL_E. For example, in case that the first gate signal GW is supplied to the (1-2)th gate line GWL_O, the first data signal VDATA1 may be supplied to the first sub-pixel SPX1 connected to the first data line DL1 and the (1-2)th gate line GWL_O, the second data signal VDATA2 may be supplied to the second sub-pixel SPX2 connected to the second data line DL2 and the (1-2)th gate line GWL_O, and the third data signal VDATA3 may be supplied to the third sub-pixel SPX3 connected to the third data line DL3 and the (1-2)th gate line GWL_O.

The pair of sub-pixels SPX_E and SPX_O may be symmetrical to each other with respect to the corresponding data line DL. For example, the pair of first sub-pixels SPX1 and SPX1 may be symmetrical to each other with respect to the first data line DL1. For example, the pair of second sub-pixels SPX2 and SPX2 may be symmetrical to each other with respect to the second data line DL2. For example, the pair of third sub-pixels SPX3 and SPX3 may be symmetrical to each other with respect to the third data line DL3.

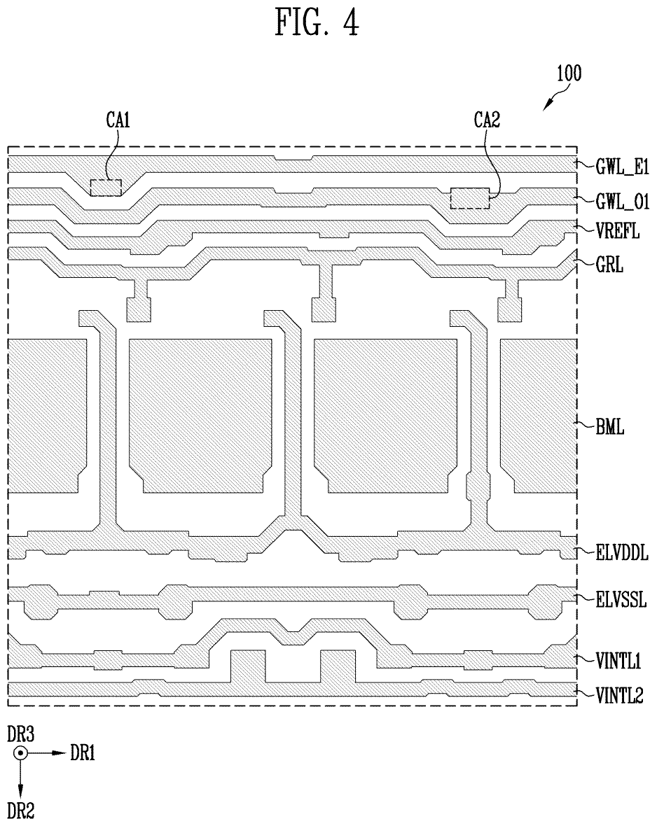

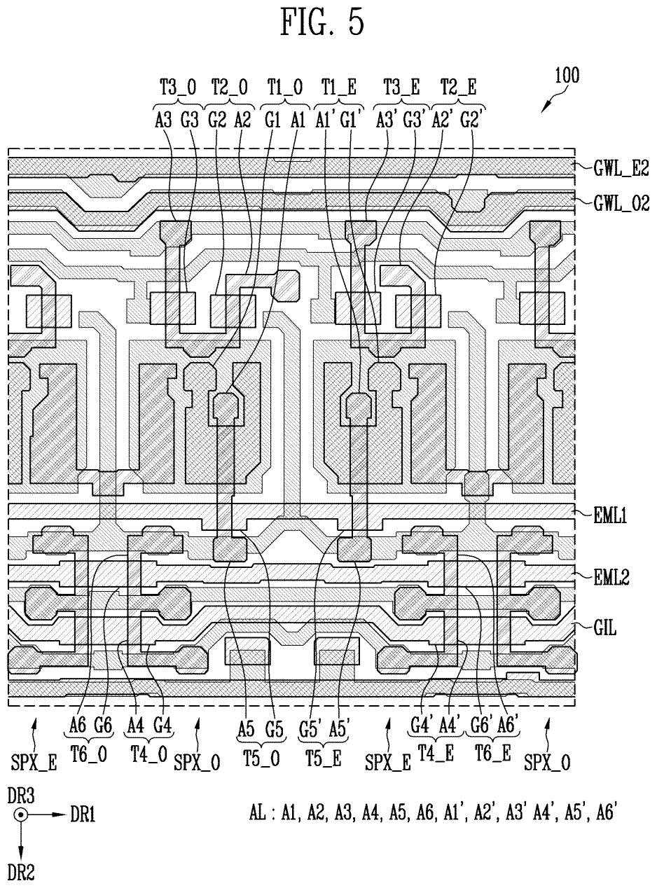

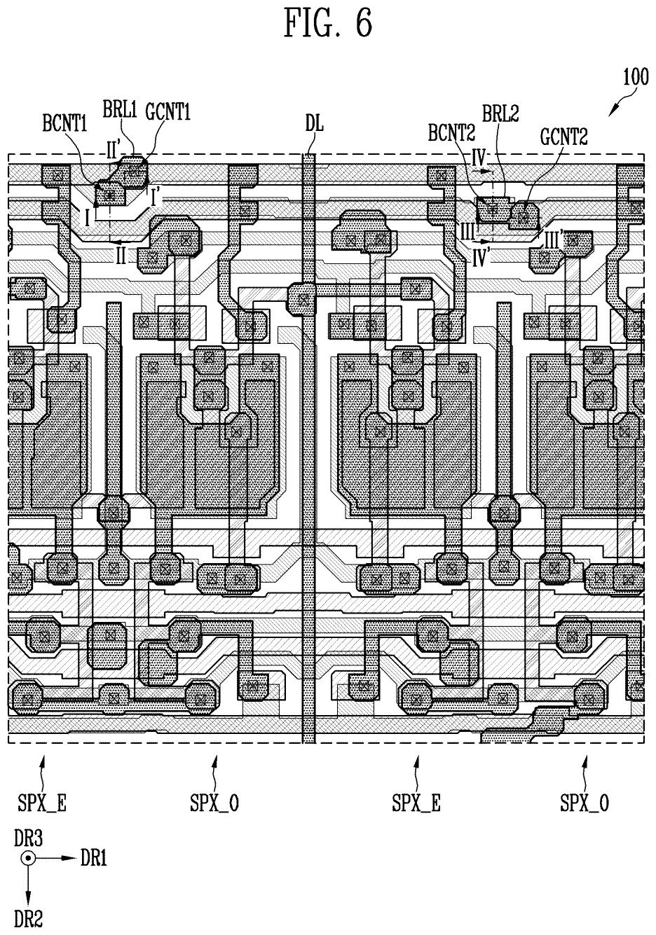

FIGS. 4 to 6 are plan views schematically illustrating layouts of the display device in accordance with an embodiment of the disclosure. FIG. 4 schematically illustrates a layout of a first conductive layer of the display device 100, FIG. 5 schematically illustrates a layout of an active layer AL and a second conductive layer of the display device 100, and FIG. 6 schematically illustrates a layout of a third conductive layer of the display device 100.

Referring to FIG. 4, a first conductive layer may include a (1-1-1)th gate line GWL_E1, a (1-2-1)th gate line GWL_O1, a reference line VREFL, a second gate line GRL, bottom metal layers BML, a first driving line ELVDDL, a second driving line ELVSSL, a first initialization line VINTL1, and a second initialization line VINTL2.

The (1-1-1)th gate line GWL_E1 may generally extend in the first direction DR1. A contact area CA1 for forming a first contact hole BCNT1 (see FIG. 6) may be defined in the (1-1-1)th gate line GWL_E1. The contact area CA1 may be located between the (1-1-1)th gate line GWL_E1 and the (1-2-1)th gate line GWL_O1.

The (1-2-1)th gate line GWL_O1 may generally extend in the first direction DR1. The (1-2-1)th gate line GWL_O1 may be spaced apart from the (1-1-1)th gate line GWL_E1 in the second direction DR2. A contact area CA2 for forming a second contact hole BCNT2 (see FIG. 6) may be defined in the (1-2-1)th gate line GWL_O1. The contact area CA2 may be located between the (1-1-1)th gate line GWL_E1 and the (1-2-1)th gate line GWL_O1.

The reference line VREFL may generally extend in the first direction DR1. The reference line VREFL may be spaced apart from the (1-2-1)th gate line GWL_O1 in the second direction DR2.

The second gate line GRL may generally extend in the first direction DR1. The second gate line GRL may partially extend in the second direction DR2. The second gate line GRL may be spaced apart from the reference line VREFL in the second direction DR2.

The bottom metal layers BML may be formed in an island shape having a selectable size. The bottom metal layers BML may be spaced apart from each other in the first direction DR1.

The first driving line ELVDDL may generally extend in the first direction DR1. The first driving line ELVDDL may partially extend in the second direction DR2 to be located between the bottom metal layers BML.

The second driving line ELVSSL may generally extend in the first direction DR1. The second driving line ELVSSL may be spaced apart from the first driving line ELVDDL in the second direction DR2.

The first initialization line VINTL1 may be an initialization line VINTL (see FIG. 2) connected to second sub-pixels SPX2 (see FIG. 3) and third sub-pixels SPX (see FIG. 3). The first initialization line VINTL1 may generally extend in the first direction DR1. The first initialization line VINTL1 may be spaced apart from the second driving line ELVSSL in the second direction DR2.

The second initialization line VINTL2 may be an initialization line VINTL connected to first sub-pixels SPX1 (see FIG. 3). The second initialization line VINTL2 may generally extend in the first direction DR1. The second initialization line VINTL2 may partially extend in the second direction DR2. The second initialization line VINTL2 may be spaced apart from the first initialization line VINTL1 in the second direction DR2.

Referring to FIG. 5, an active layer AL may be formed on the first conductive layer. The active layer AL may include a first active pattern A1, a second active pattern A2, a third active pattern A3, a fourth active pattern A4, a fifth active pattern A5, and a sixth active pattern A6 of a sub-pixel SPX_E connected to a (1-1)th gate line GWL_E. Also, the active layer AL may include a first active pattern A1′, a second active pattern A2′, a third active pattern A3′, a fourth active pattern A4′, a fifth active pattern A5′, and a sixth active pattern A6′ of a sub-pixel SPX_E connected to a (1-2)th gate line GWL_O.

A second conductive layer may be formed on the active layer AL. The second conductive layer may include a (1-1-2)th gate line GWL_E2, a (1-2-2)th gate line GWL_O2, a first emission control line EML1, a second emission control line EML2, and a third gate line GIL.

The (1-1-2)th gate line GWL_E2 may generally extend in the first direction DR1. The (1-1-2)th gate line GWL_E2 may overlap the (1-1-1)th gate line GWL_E1 (see FIG. 4) and offset from the contact area CA1 (see FIG. 4) in a plan view. For example, the (1-1-2)th gate line GWL_E2 may not overlap the contact area CA1 in a plan view.

The (1-2-2)th gate line GWL_O2 may generally extend in the first direction DR1. The (1-2-2)th gate line GWL_O2 may overlap the (1-2-1)th gate line GWL_O1 (see FIG. 4) and offset from the contact area CA2 (see FIG. 4) in a plan view. For example, the (1-2-2)th gate line GWL_O2 may not overlap the contact area CA2 in a plan view.

The first emission control line EML1, the second emission control line EML2, and the third gate line GIL may generally extend in the first direction DR1, and be spaced apart from each other in the second direction DR2.

First gate electrodes G1 and G1′ may be formed on the first active patterns A1 and A1′, respectively. The first gate electrodes G1 and G1′ may overlap channel regions of the first active patterns A1 and A1′ in a plan view, respectively. The first gate electrode G1 and the first active pattern A1 may constitute a first transistor T1_O of a sub-pixel SPX_O. The first gate electrode G1′ and the first active pattern A1′ may constitute a first transistor T1_E of a sub-pixel SPX_E.

Second gate electrodes G2 and G2′ may be formed on the second active patterns A2 and A2′, respectively. The second gate electrodes G2 and G2′ may overlap channel regions of the second active patterns A2 and A2′ in a plan view, respectively. The second gate electrode G2 and the second active pattern A2 may constitute a second transistor T2_O of the sub-pixel SPX_O. The second gate electrode G2′ and the second active pattern A2′ may constitute a second transistor T2_E of the sub-pixel SPX_E.

Third gate electrodes G3 and G3′ may be formed on the third active patterns A3 and A3′, respectively. The third gate electrodes G3 and G3′ may overlap channel regions of the third active patterns A3 and A3′ in a plan view. The third gate electrode G3 and the third active pattern A3 may constitute a third transistor T3_O of the sub-pixel SPX_O. The third gate electrode G3′ and the third active pattern A3′ may constitute a third transistor T3_E of the sub-pixel SPX_E.

Fourth gate electrodes G4 and G4′ may be formed on the fourth active patterns A4 and A4′, respectively. The fourth gate electrodes G4 and G4′ may overlap channel regions of the second active patterns A4 and A4′ in a plan view, respectively. The fourth gate electrode G4 and the fourth active pattern A4 may constitute a fourth transistor T4_O of the sub-pixel SPX_O. The fourth gate electrode G4′ and the fourth active pattern A4′ may constitute a fourth transistor T4_E of the sub-pixel SPX_E.

Fifth gate electrodes G5 and G5′ may be formed on the fifth active patterns A5 and A5′, respectively. The fifth gate electrodes G5 and G5′ may overlap channel regions of the fifth active patterns A5 and A5′ in a plan view, respectively. The fifth gate electrode G5 and the fifth active pattern A5 may constitute a fifth transistor T5_O of the sub-pixel SPX_O. The fifth gate electrode G5′ and the fifth active pattern A5′ may constitute a fifth transistor T5_E of the sub-pixel SPX_E.

Sixth gate electrodes G6 and G6′ may be formed on the sixth active patterns A6 and A6′, respectively. The sixth gate electrodes G6 and G6′ may overlap channel regions of the sixth active patterns A6 and A6′ in a plan view, respectively. The sixth gate electrode G6 and the sixth active pattern A6 may constitute a sixth transistor T6_O of the sub-pixel SPX_O. The sixth gate electrode G6′ and the sixth active pattern A6′ may constitute a sixth transistor T6_E of the sub-pixel SPX_E.

Referring to FIG. 6, a third conductive layer may include a data line DL, a first bridge line BRL1, a second bridge line BRL2, and contact holes GCNT1, GCNT2, BCNT1, and BCNT2.

The data line DL may extend in the second direction DR2. The data line DL may partially extend in the first direction DR1. A pair of sub-pixels SPX_O and SPX_E may be connected to the data line DL.

The first bridge line BRL1 may be a connection line connecting the (1-1-1)th gate line GWL_E1 (see FIG. 4) and the (1-1-2)th gate line GWL_E2 (see FIG. 5) to each other. The first bridge line BRL1 may be formed on the (1-1-1)th gate line GWL_E1 and the (1-1-2)th gate line GWL_E2. A contact hole BCNT1 (or first contact hole) may be formed on the contact area CA1 (see FIG. 4) of the (1-1-1)th gate line GWL_E1. A contact hole GCNT1 may be formed on the (1-1-2)th gate line GWL_E2. An end of the first bridge line BRL1 may be connected to the (1-1-1)th gate line GWL_E1 through the contact hole BCNT1. Another end of the first bridge line BRL1 may be connected to the (1-1-2)th gate line GWL_E2 through the GCNT1. As such, in case that the (1-1)th gate line GWL_E (see FIG. 3) is formed as a double line, the resistance of the (1-1)th gate line GWL_E (see FIG. 3) may be decreased, and thus a sufficient time for writing the data signal VDATA (see FIG. 2) may be secured. The contact hole BCNT1 may be located between the (1-1-2)th gate line GWL_E2 and the (1-2-2)th gate line GWL_O2 (see FIG. 5), so that a space for forming the contact hole BCNT1 while avoiding the (1-1-2)th gate line GWL_E2 may be reduced.

The second bridge line BRL2 may be a connection line connecting the (1-2-1)th gate line GWL_O1 (see FIG. 4) and the (1-2-2)th gate line GWL_O2 (see FIG. 5) to each other. The second bridge line BRL2 may be formed on the (1-2-1)th gate line GWL_O1 and the (1-2-2)th gate line GWL_O2. A contact hole BCNT2 (or second contact hole) may be formed on the contact area CA2 (see FIG. 4) of the (1-2-1)th gate line GWL_O1. A contact hole GCNT2 may be formed on the (1-2-2)th gate line GWL_O2. An end of the second bridge line BRL2 may be connected to the (1-2-1)th gate line GWL_O1 through the contact hole BCNT2. Another end of the second bridge line BRL2 may be connected to the (1-2-2)th gate line GWL_O2 through the contact hole GCNT2. As such, in case that the (1-2)th gate line GWL_O (see FIG. 3) is formed as a double line, the resistance of the (1-2)th gate line GWL_O may be decreased, and thus a sufficient time for writing the data signal VDATA may be secured. The contact hole BCNT2 may be located between the (1-1-2)th gate line GWL_E2 and the (1-2-2)th gate line GWL_O2, so that a space for forming the contact hole BCNT2 while avoiding the (1-2-2)th gate line GWL_O2 may be reduced.

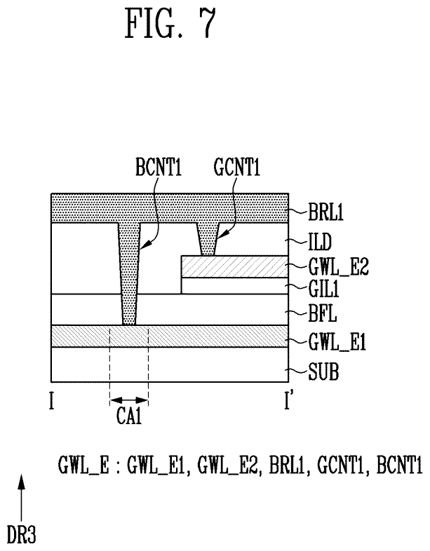

FIG. 7 is a schematic cross-sectional view taken along line I-I′ of FIG. 6 in accordance with an embodiment of the disclosure.

Referring to FIG. 7, a (1-1-1)th gate line GWL_E1 may be located on a substrate SUB. The substrate SUB may be a glass substrate, a polyimide (PI) substrate, or the like, but the disclosure is not necessarily limited thereto. The (1-1-1)th gate line GWL_E1 may include a metal material such as aluminum or copper, but the disclosure is not necessarily limited thereto.

A buffer layer BFL may be located on the (1-1-1)th gate line GWL_E1. The buffer layer BFL may include an insulating material such as an organic insulating material or an inorganic insulating material.

A first gate insulating layer GIL1 may be located on a portion of the buffer layer BFL. The first gate insulating layer GIL1 may include an insulating material such as an organic insulating material or an inorganic insulating material.

A (1-1-2)th gate line GWL_E2 may be located on the first gate insulating layer GIL1. The (1-1-2)th gate line GWL_E2 may include a metal material such as aluminum or copper, but the disclosure is not necessarily limited thereto.

An interlayer insulating layer ILD covering the first gate insulating layer GIL1 and the (1-1-2)th gate line GWL_E2 may be located on the buffer layer BFL. The interlayer insulating layer ILD may include an insulating material such as an organic insulating material or an inorganic insulating material.

A first bridge line BRL1 may be located on the interlayer insulating layer ILD. The first bridge line BRL1 may include a metal material such as aluminum or copper, but the disclosure is not necessarily limited thereto. A contact hole BCNT1 may be located in a contact area CA1 of the (1-1-1)th gate line GWL_E1. Accordingly, the contact hole BCNT1 may be connected to the (1-1-1)th gate line GWL_E1 while avoiding the (1-1-2)th gate line GWL_E2. An end of the first bridge line BRL1 may be connected to the (1-1-1)th gate line GWL_E1 through the contact hole BCNT1 penetrating the interlayer insulating layer ILD and the buffer layer BFL. Another end of the first bridge line BRL1 may be connected to the (1-1-2)th gate line GW_E2 through a contact hole GCNT1 penetrating the interlayer insulating layer ILD.

A (1-1)th gate line GWL_E may include the (1-1-1)th gate line GWL_E, the (1-1-2)th gate line GWL_E2, the first bridge line BRL1, and the contact holes GCNT1 and BCNT1. The (1-1-1)th gate line GWL_E and the (1-1-2)th gate line GWL_E2 may form a double line of the (1-1)th gate line GWL_E. The first bridge line BRL1 and the contact holes BCNT1 and GCNT1 may form a connection line connecting the double line of the (1-1)th gate line GWL_E.

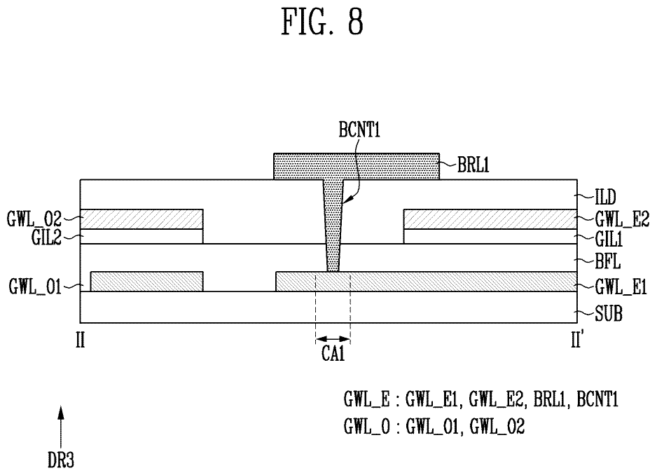

FIG. 8 is a schematic cross-sectional view taken along line II-II′ of FIG. 6 in accordance with an embodiment of the disclosure. For convenience of description, in FIG. 8, descriptions of portions overlapping the portions shown in FIG. 7 will be omitted or simplified.

Referring to FIG. 8, a (1-2-1)th gate line GWL_O1 spaced apart from the (1-1-1)th gate line GWL_E1 may be located on the substrate SUB. The (1-2-1)th gate line GWL_O1 and the (1-1-1)th gate line GWL_E1 may include a substantially same material.

The buffer layer BFL covering the (1-1-1)th gate line GWL_E1 and the (1-2-1)th gate line GWL_O1 may be located on the substrate SUB.

A second gate insulating layer GIL2 spaced apart from the first gate insulating layer GIL1 may be located on the buffer layer BFL. The second gate insulating layer GIL2 and the first gate insulating layer GIL1 may include a substantially same material.

A (1-2-2)th gate line GWL_O2 may be located on the second gate insulating layer GIL2. The (1-2-2)th gate line GWL_O2 and the (1-1-2)th gate line GWL_E2 may include a substantially same material. The (1-2-1)th gate line GWL_O1 and the (1-2-2)th gate line GWL_O2 may form a double line of a (1-2)th gate line GWL_O.

The interlayer insulating layer ILD covering the first gate insulating layer GIL1, the second gate insulating layer GIL2, the (1-2-1)th gate line GWL_E2, and the (1-2-2)th gate line GWL_O2 may be located on the buffer layer BFL.

The contact hole BCNT1 penetrating the interlayer insulating layer ILD and the buffer layer BFL may be located between the (1-1-2)th gate line GWL_E2 and the (1-2-2)th gate line GWL_O2. In case that the contact hole BCNT1 is formed at the above-described position, a space for forming the contact hole BCNT1 connecting the first bridge pattern BRL1 and the (1-1-1)th gate line GWL_E1 to each other while avoiding the (1-1-2)th gate line GWL_E2 may be reduced. For example, a space for forming the (1-1)th gate line GWL_E as the double line may be ensured.

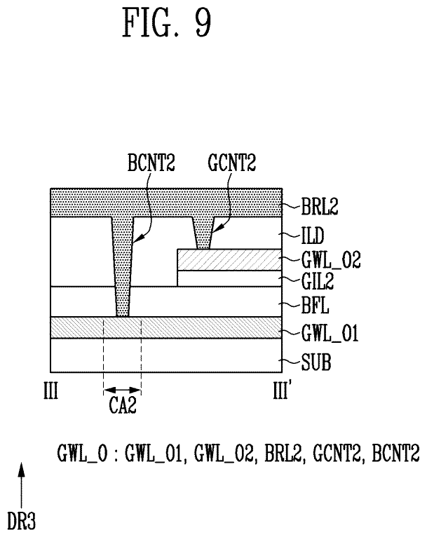

FIG. 9 is a schematic cross-sectional view taken along line III-III′ of FIG. 6 in accordance with an embodiment of the disclosure. For convenience of description, in FIG. 9, descriptions of portions overlapping the portions shown in FIGS. 7 and 8 will be omitted or simplified.

Referring to FIG. 9, a (1-2-1)th gate line GWL_O1 may be located on the substrate SUB. The buffer layer BFL may be located over the (1-2-1)th gate line GWL_O1. A second gate insulating layer GIL2 may be located on a portion of the buffer layer BFL. A (1-2-2)th gate line GWL_O2 may be located on the second gate insulating layer GIL2. The interlayer insulating layer ILD covering the second gate insulating layer GIL2 and the (1-2-2)th gate line GWL_O2 may be located on the buffer layer BFL.

A second bridge line BRL2 may be located on the interlayer insulating layer ILD. The second bridge line BRL2 and the first bridge line BRL1 (see FIG. 7) may include a substantially same material. A contact hole BCNT2 may be located on a contact area CA2 of the (1-2-1)th gate line GWL_O1. Accordingly, the contact hole BCNT2 may be connected to the (1-2-1)th gate line GWL_O1 while avoiding the (1-2-2)th gate line GWL_O2. An end of the second bridge line BRL2 may be connected to the (1-2-1)th gate line GWL_O1 through the contact hole BCNT2 penetrating the interlayer insulating layer ILD and the buffer layer BFL. Another end of the second bridge line BRL2 may be connected to the (1-2-2)th gate line GWL_O2 through a contact hole GCNT2 penetrating the interlayer insulating layer ILD.

A (1-2)th gate line GWL_O may include the (1-2-1)th gate line GWL_O1, the (1-2-2)th gate line GWL_O2, the second bridge line BRL2, and the contact holes GCNT2 and BCNT2. The (1-2-1)th gate line GWL_O1 and the (1-2-2)th gate line GWL_O2 may form a double line of the (1-2)th gate line GWL_O. The second bridge line BRL2 and the contact holes BCNT2 and GCNT2 may form a connecting line connecting the double line of the (1-2)th gate line GWL_O.

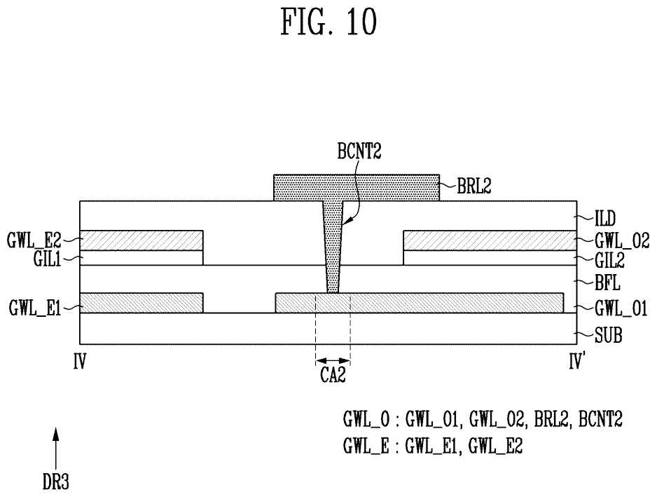

FIG. 10 is a schematic cross-sectional view taken along line IV-IV′ of FIG. 6 in accordance with an embodiment of the disclosure. For convenience of illustration, in FIG. 10, descriptions of portions overlapping the portions shown in FIGS. 7 to 9 will be omitted or simplified.

Referring to FIG. 10, the contact hole BCNT2 penetrating the interlayer insulating layer ILD and the buffer layer BFL may be located between the (1-1-2)th gate line GWL_E2 and the (1-2-2)th gate line GWL_O2. In case that the contact hole BCNT2 is formed at the above-described position, a space for forming the contact hole BCNT2 connecting the second bridge line BRL2 and the (1-2-1)th gate line GWL_O1 to each other while avoiding the (1-2-2)th gate line GWL_O2 may be reduced. For example, a space for forming the (1-2)th gate line GWL_O as the double line may be ensured.

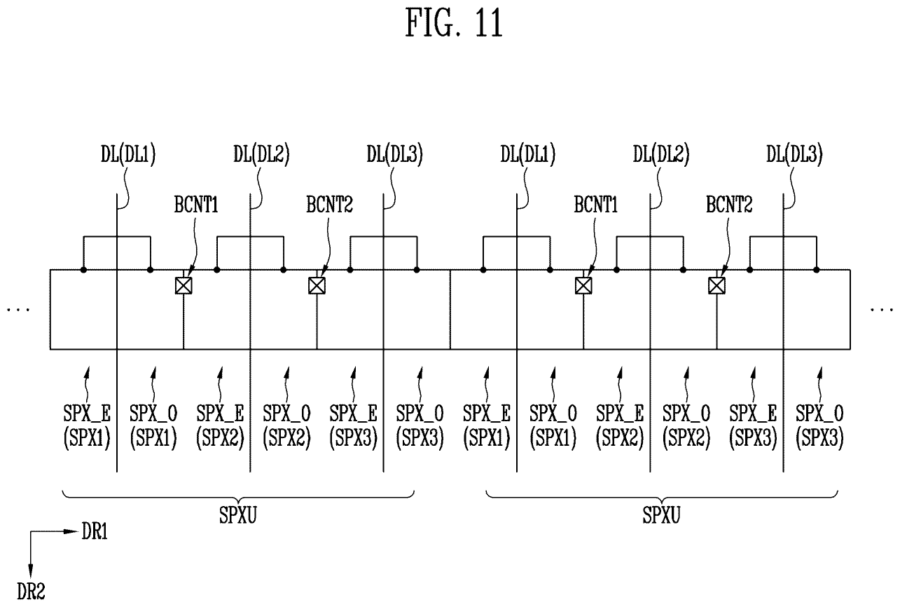

FIG. 11 is a schematic diagram schematically illustrating an arrangement of first and second contact holes in accordance with an embodiment of the disclosure.

Referring to FIG. 11, a contact hole BCNT1 (or first contact hole) may be located between sub-pixels SPX_O and SPX_E while avoiding a data line DL. For example, the contact hole BCNT1 may not be located between a pair of first sub-pixels SPX1 and SPX1 commonly connected to a first data line DL1, between a pair of second sub-pixels SPX2 and SPX2 commonly connected to a second data line DL2, and between a pair of third sub-pixels SPX3 and SPX3 commonly connected to a third data line DL3. For example, the contact hole BCNT1 may be located between a first sub-pixel SPX1 of the pair of first sub-pixels SPX1 and SPX1, which is connected to the (1-2)th gate line GWL_O (see FIG. 3) and a second sub-pixel SPX2 of the pair of second sub-pixels SPX2 and SPX2, which is connected to the (1-1)th gate line GWL_E (see FIG. 3). For example, the contact hole BCNT1 may be commonly located in the first sub-pixel SPX1 connected to the (1-2)th gate line GWL_O and the second sub-pixel SPX2 connected to the (1-1)th gate line GWL_E. In other words, the contact hole BCNT1 may be shared by the first sub-pixel SPX1 connected to the (1-2)th gate line GWL_O and the second sub-pixel SPX2 connected to the (1-1)th gate line GWL_E.

A contact hole BCNT2 (or second contact hole) may be located between sub-pixels SPX_O and SPX_E while avoiding a data line DL. For example, the contact hole BCNT2 may not be located between the pair of first sub-pixels SPX1 and SPX1 commonly connected to the first data line DL1, between the pair of second sub-pixels SPX2 and SPX2 commonly connected to the second data line DL2, and between the pair of third sub-pixels SPX3 and SPX3 commonly connected to the third data line DL3. For example, the contact hole BCNT2 may be located between a second sub-pixel SPX2 of the pair of second sub-pixels SPX2 and SPX2, which is connected to the (1-2)th gate line GWL_O and a third sub-pixel SPX3 of the pair of third sub-pixels SPX3 and SPX3, which is connected to the (1-1)th gate line GWL_E. For example, the contact hole BCNT2 may be commonly located in the second sub-pixel SPX2 connected to the (1-2)th gate line GWL_O and the third sub-pixel SPX3 connected to the (1-1)th gate line GWL_E. In other words, the contact hole BCNT2 may be shared by the second sub-pixel SPX2 connected to the (1-2)th gate line GWL_O and the third sub-pixel SPX3 connected to the (1-1)th gate line GWL_E.

The contact holes BCNT1 and BCNT2 may be repeatedly arranged in a sub-pixel unit SPXU configured with six sub-pixels.

For example, the contact hole BCNT1 may be located in each sub-pixel unit SPXU configured with a pair of first sub-pixels SPX1 and SPX1 commonly connected to a first data line DL1, a pair of second sub-pixels SPX2 and SPX2 commonly connected to a second data line DL2, and a pair of third sub-pixels SPX3 and SPX3 commonly connected to a third data line DL3.

For example, the contact hole BCNT2 may be located in each sub-pixel unit SPXU configured with a pair of first sub-pixels SPX1 and SPX1 commonly connected to a first data line DL1, a pair of second sub-pixels SPX2 and SPX2 commonly connected to a second data line DL2, and a pair of third sub-pixels SPX3 and SPX3 commonly connected to a third data line DL3.

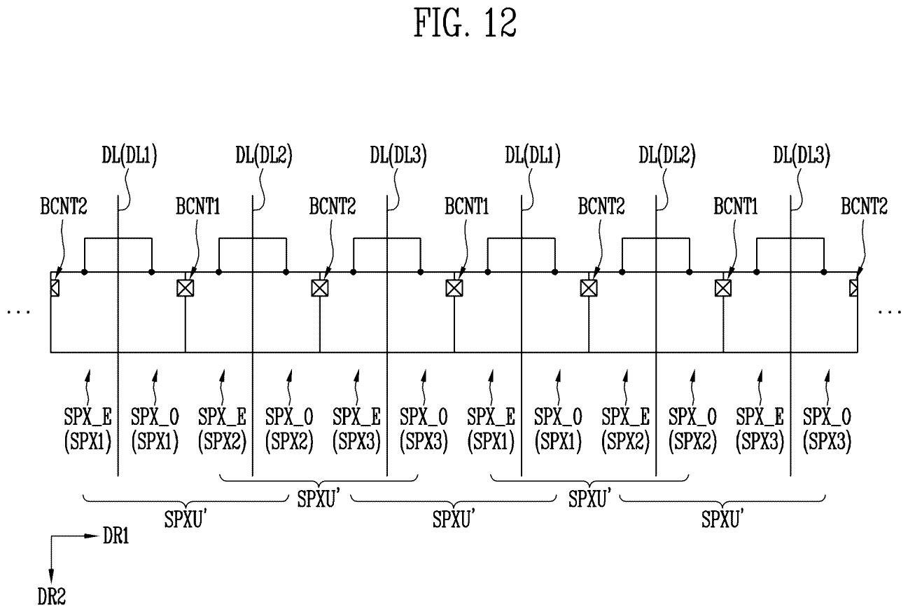

FIG. 12 is a schematic diagram schematically illustrating an arrangement of first and second contact holes in accordance with an embodiment of the disclosure. For convenience, in FIG. 12, descriptions of portions overlapping the portions shown in FIG. 11 will be omitted or simplified.

Referring to FIG. 12, contact holes BCNT1 and BCNT2 may be repeatedly arranged in a sub-pixel unit SPXU′ configured with four sub-pixels.

For example, a contact hole BCNT1 may be located in each sub-pixel unit SPXU′ configured with a pair of first sub-pixels SPX1 and SPX1 commonly connected to a first data line DL1 and a pair of second sub-pixels SPX2 and SPX2 commonly connected to a second data line DL2. For example, a contact hole BCNT1 may be located in each sub-pixel unit SPXU′ configured with a pair of third sub-pixels SPX3 and SPX3 commonly connected to a third data line DL3 and a pair of first sub-pixels SPX1 and SPX1 commonly connected to a first data line DL1. For example, a contact hole BCNT1 may be located in each sub-pixel unit SPXU′ configured with a pair of second sub-pixels SPX2 and SPX2 commonly connected to a second data line DL2 and a pair of third sub-pixels SPX3 and SPX3 commonly connected to a third data line DL3.

For example, a contact hole BCNT2 may be located in each sub-pixel unit SPXU′ configured with a pair of second sub-pixels SPX2 and SPX2 commonly connected to a second data line DL2 and a pair of third sub-pixels SPX3 and SPX3 commonly connected to a third data line DL3. For example, a contact hole BCNT2 may be located in each sub-pixel unit SPXU′ configured with a pair of first sub-pixels SPX1 and SPX1 commonly connected to a first data line DL1 and a pair of second sub-pixels SPX2 and SPX2 commonly connected to a second data line DL2. For example, a second contact hole BCNT2 may be located in each sub-pixel unit (not shown) configured with a pair of third sub-pixels SPX3 and SPX3 commonly connected to a third data line DL3 and a pair of first sub-pixels SPX1 and SPX1 commonly connected to a first data line DL1.

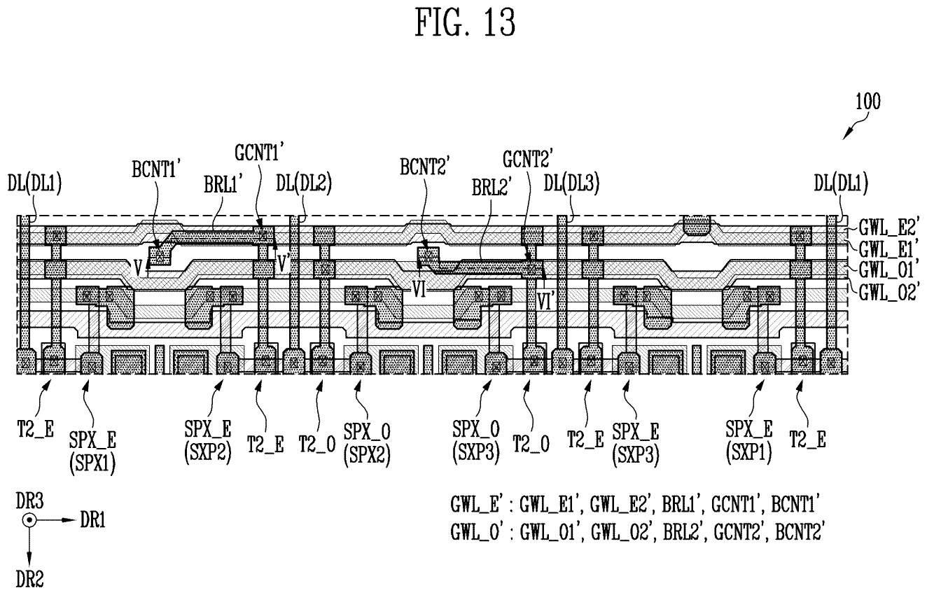

FIG. 13 is a plan view schematically illustrating a layout of the display device in accordance with an embodiment of the disclosure. For convenience, in FIG. 13, descriptions of portions overlapping the portions shown in FIGS. 4 to 6 will be omitted or simplified.

Referring to FIG. 13, a (1-1-1)th gate line GWL_E1′ may generally extend in the first direction DR1. A (1-2-1)th gate line GWL_O1′ may generally extend in the first direction DR1, and be spaced apart from the (1-1-1)th gate line GWL_E1′ in the second direction DR2.

A (1-1-2)th gate line GWL_E2′ may be located on the (1-1-1)th gate line GWL_E1′. The (1-1-2)th gate line GWL_E2′ may overlap the (1-1-1)th gate line GWL_E1′ and offset from a contact hole BCNT1′ in a plan view. A (1-2-2)th gate line GWL_O2′ may be located on the (1-2-1)th gate line GWL_O1′. The (1-2-2)th gate line GWL_O2′ may overlap the (1-2-1)th gate line GWL_O1′ and offset from a contact hole BCNT2′ in a plan view.

A data line DL may be located between a pair of sub-pixels SPX_E and SPX_O. For example, a second data line DL2 may be located between a pair of second sub-pixels SPX2 and SPX2, and the pair of second sub-pixels SPX2 and SPX2 may be commonly connected to the second data line DL2. For example, a third data line DL3 may be located between a pair of third sub-pixels SPX3 and SPX3, and the pair of third sub-pixels SPX3 and SPX3 may be commonly connected to the third data line DL3. For convenience, in FIG. 13, one first sub-pixel SPX1 connected to a first data line DL1 is illustrated according to an embodiment.

A pair of sub-pixels SPX_E and SPX_O may be symmetrical to each other with respect to a corresponding data line DL. For example, a pair of second sub-pixels SPX2 and SPX2 may be located symmetrical to each other with respect to a second data line DL2. For example, a pair of third sub-pixels SPX3 and SPX3 may be located symmetrical to each other with respect to a third data line DL3. A pair of first sub-pixels SPX1 and SPX1 (see FIG. 11) may be located symmetrical to each other with respect to a first data line DL1 as described above.

A first bridge line BRL1′ may be located on the (1-1-1)th gate line GWL_E1′ in which the contact hole BCNT1′ is located. An end of the first bridge line BRL1′ may be connected to the (1-1-1)th gate line GWL_E1′ through the contact hole BCNT1′. The first bridge line BRL1′ may be located on the (1-1-2)th gate line GWL_E2′. The first bridge line BRL1′ may extend in the first direction DR1 to overlap the (1-1-2)th gate line GWL_E2′ in a plan view. Accordingly, an increase in capacitance of a (1-1)th gate line GWL_E′ may be prevented, and thus a sufficient time for writing a data signal VDATA (see FIG. 2) may be secured. Another end of the first bridge line BRL1′ may be connected to the (1-1-2)th gate line GWL_E′ through a contact hole GCNT1′. The first bridge line BRL1′ may extend in the second direction DR2 to be connected to a second transistor T2_E of a sub-pixel SPX_E (or second sub-pixel SPX2).

A second bridge line BRL2′ may be located on the (1-2-1)th gate line GWL_O1′ in which the contact hole BCNT2′ is located. An end of the second bridge line BRL2′ may be connected to the (1-2-1)th gate line GWL_O1′ through the contact hole BCNT2′. The second bridge line BRL2′ may be located on the (1-2-2)th gate line GWL_O2′. The second bridge line BRL2′ may extend in the first direction DR1 to overlap the (1-2-2)th gate line GWL_O2′ in a plan view. Accordingly, an increase in capacitance of a (1-2)th gate line GWL_O′ may be prevented, and thus a sufficient time for writing the data signal VDATA may be ensured. Another end of the second bridge line BRL2′ may be connected to the (1-2-2)th gate line GWL_O2′ through a contact hole GCNT2′. The second bridge line BRL2′ may extend in the second direction DR2 to be connected to a second transistor T2_O of a sub-pixel SPX_O (or third sub-pixel SPX3).

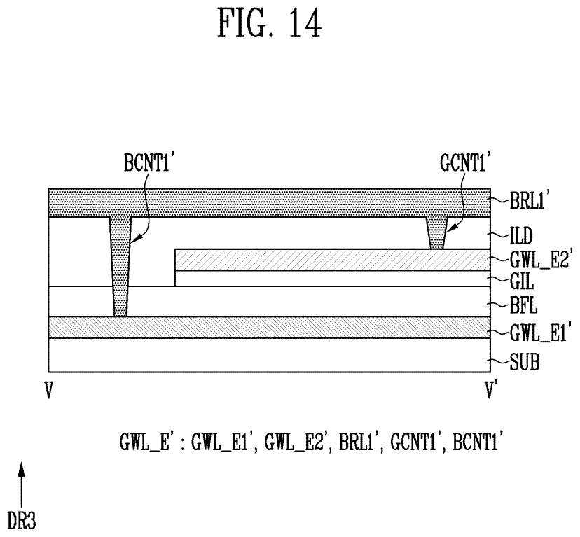

FIG. 14 is a schematic cross-sectional view taken along line V-V′ of FIG. 13. For convenience, in FIG. 14, descriptions of portions overlapping the portions shown in FIG. 7 will be simplified or omitted.

Referring to FIG. 14, the contact hole BCNT1′ may be located on the (1-1-1)th gate line GWL_E1′ while avoiding the (1-1-2)th gate line GWL_E2′. An end of the contact hole BCNT1′ may be connected to the (1-1-1)th gate line GWL_E1′, and another end of the contact hole BCNT1′ may be connected to the end of the first bridge line BRL1′. The first bridge BRL1′ connected to the another end of the contact hole BCNT1′ may extend in the first direction DR1 (see FIG. 13) to overlap the (1-1-2)th gate line GWL_E2′ in a plan view. An end of the contact hole GCNT1′ may be connected to the (1-1-2)th gate line GWL_E2′, and another end of the contact hole GCNT1′ may be connected to the another end of the first bridge line BRL1′. A double line including the (1-1-1)th gate line GWL_E1′ and the (1-1-2)th gate line GWL_E2′ may be formed, so that the resistance of the (1-1)th gate line GWL_E′ may be decreased. The first bridge line BRL1′ connected to the contact holes BCNT1′ and GCNT1′ may overlap the (1-1-2)th gate line GWL_E2′ in a plan view, so that an increase in capacitance of the (1-1)th gate line GWL_E′ may be prevented.

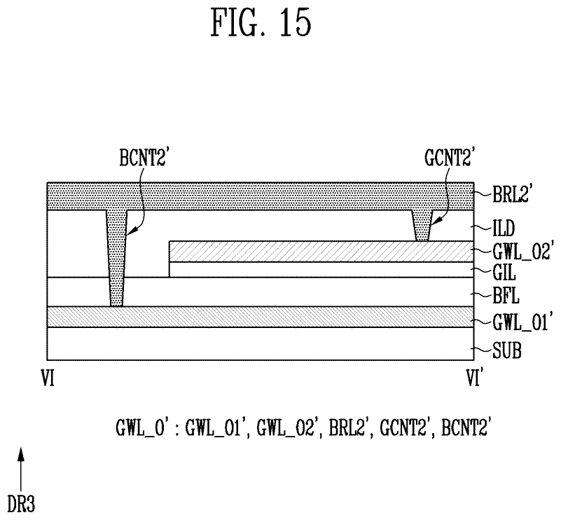

FIG. 15 is a schematic cross-sectional view taken along line VI-VI′ of FIG. 13. For convenience, in FIG. 15, descriptions of portions overlapping the portions shown in FIG. 7 will be simplified or omitted.

Referring to FIG. 15, the contact hole BCNT2′ may be located on the (1-2-1)th gate line GWL_O1′ while avoiding the (1-2-2)th gate line GWL_O2′. An end of the contact hole BCNT2′ may be connected to the (1-2-1)th gate line GWL_O1′, and another end of the contact hole BCNT2′ may be connected to the one end of the second bridge line BRL2′. The second bridge line BRL2′ connected to the another end of the contact hole BCNT2′ may extend in the first direction DR1 (see FIG. 13) to overlap the (1-2-2)th gate line GWL_O2′ in a plan view. An end of the contact hole GCNT2′ may be connected to the (1-2-2)th gate line GWL_O2′, and another end of the contact hole GCNT2′ may be connected to the another end of the second bridge line BRL2′. A double line including the (1-2-1)th gate line GWL_O1′ and the (1-2-2)th gate line GWL_O2′ may be formed, so that the resistance of the (1-2)th gate line GWL_O′ may be decreased. The second bridge line BRL2′ connected to the contact holes BCNT2′ and GCNT2′ may overlap the (1-2-2)th gate line GWL_O2′ in a plan view, so that an increase in capacitance of the (1-2)th gate line GWL_O′ may be prevented.

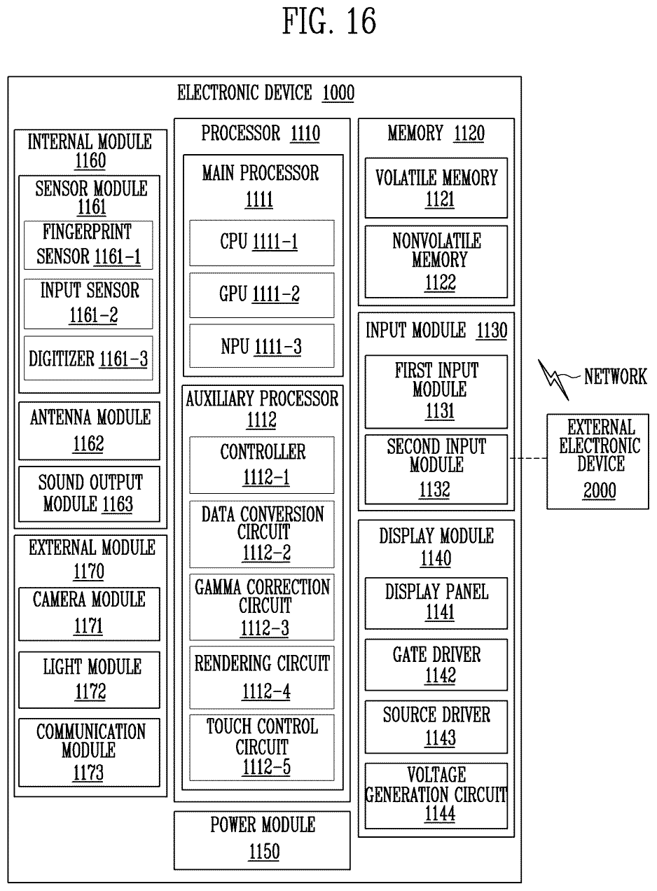

FIG. 16 is a schematic block diagram of an electronic device in accordance with an embodiment of the disclosure.

Referring to FIG. 16, an electronic device 1000 may output various information through a display module 1140. In case that a processor 1110 executes an application stored in a memory 1120, the display module 1140 may provide application information to a user through a display panel 1141.

The processor 1110 may acquire an external input through an input module 1130 or a sensor module 1161, and execute an application corresponding to the external input.

For example, in case that the user selects a camera icon (or camera application icon) displayed on the display panel 1141, the processor 1110 may acquire a user input through an input sensor 1161-2, and activate a camera module 1171. The processor 1110 may transfer, to the display module 1140, image data corresponding to a photographed image acquired through the camera module 1171. The display module 1140 may display an image corresponding to the photographed image through the display panel 1141.

For example, in case that personal information authentication is executed in the display module 1140, a fingerprint sensor 1161-1 may acquire input fingerprint information as input data. The processor 1110 may compare the input data acquired through the fingerprint sensor 1161-1 with authentication data stored in the memory 1120, and execute an application according to a comparison result. The display module 1140 may display information executed according to a logic of the application through the display panel 1141. The fingerprint sensor 1161-1 may acquire fingerprint information in the entire area of the display panel 1141.

For example, in case that a music streaming icon displayed on the display module 1140 is selected, the processor 1110 may acquire a user input through the input sensor 1161-2, and activate a music streaming application stored in the memory 1120. In case that a music play command is input in the music streaming application, the processor 1110 may activate a sound output module 1163, thereby providing the user with sound information which accords with the music play command.

In the above, operations of the electronic device 1000 have been briefly described. Hereinafter, components of the electronic device 1000 will be described in detail. Some of the components of the electronic device 1000, which will be described below, may be integrated to be provided as one component, and one component may be separated into two or more components to be provided.

The electronic device 1000 may communicate with an external electronic device 2000 through a network (e.g., a short-range wireless communication network or a long-range wireless communication network). The electronic device 1000 may include the processor 1110, the memory 1120, the input module 1130, the display module 1140, a power module 1150, an internal module 1160, and an external module 1170. At least one of the above-described components may be omitted, or one or more other components may be added. Some components (e.g., the sensor module 1161, an antenna module 1162, and/or the sound output module 1163) among the above-described components may be integrated in another component (e.g., the display module 1140).

The processor 1110 may control at least another component (e.g., a hardware or software component) of the electronic device 1000, which is connected to the processor 1110, by executing software, and perform various processing or calculations. As at least a portion of the data processing and calculations, the processor 1110 may store, in a volatile memory 1121, a command or data, received from another component (e.g., the input module 1130, the sensor module 1161, or a communication module 1173), process the command or data, stored in the volatile memory 1121, and store result data in a nonvolatile memory 1122.

The processor 1110 may include a main processor 1111 and an auxiliary processor 1112. The main processor 1111 may include a central processing unit (CPU) 1111-1. The main processor 1111 may further include at least one of a graphic processing unit (GPU) 1111-2, a communication processor (CP), and an image signal processor (ISP). The main processor 1111 may further include a neural processing unit (NPU) 1111-3. The NPU 1111-3 may be a processor specified for processing an artificial intelligence (AI) model, and the AI model may be generated through machine learning. The AI model may include multiple artificial neural network layers. An artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-networks, or a combination thereof, but the disclosure is not necessarily limited thereto. The AI model may additionally or alternatively include a software structure, in addition to a hardware structure. At least two of the above-described processing units and the above-described processors may be implemented into one integrated component (e.g., a single chip), or be implemented as components (e.g., multiple chips) independent from each other.

The auxiliary processor 1112 may include a controller 1112-1. The controller 1112-1 may include an interface conversion circuit and a timing control circuit. For example, the controller 1112-1 may include the controller 150 shown in FIG. 1. The controller 1112-1 may receive an image signal from the main processor 1111, and convert a data format of the image signal to be suitable for interface specifications of the display module 1140, thereby outputting image data. The controller 1112-1 may output various control signals for driving of the display module 1140.

The auxiliary processor 1112 may further include a data conversion circuit 1112-2, a gamma correction circuit 1112-3, a rendering circuit 1112-4, a touch control circuit 1112-5, and the like. The data conversion circuit 1112-2 may receive image data from the controller 1112-1, and compensate the image data such that an image is displayed with a desired luminance according to a characteristic of the electronic device 1000 or a setting of the user or convert the image data for the purpose of reduction of power consumption, afterimage compensation, or the like.

The gamma correction circuit 1112-3 may convert image data, a gamma reference voltage, or the like such that an image displayed in the electronic device 1000 has a desired gamma characteristic. The rendering circuit 1112-4 may receive image data from the controller 1112-1, and render the image data by considering a pixel arrangement of the display panel 1141, and the like, applied to the electronic device 1000.

The touch control circuit 1112-5 may supply a touch signal to the input sensor 1161-2, and be supplied with a sensing signal from the input sensor 1161-2, corresponding to the touch signal.

At least one of the data conversion circuit 1112-2, the gamma correction circuit 1112-3, the rendering circuit 1112-4, and the touch control circuit 1112-5 may be integrated in another component (e.g., the main processor 1111 or the controller 1112-4). At least one of the data conversion circuit 1112-2, the gamma correction circuit 1112-3, and the rendering circuit 1112-4 may be integrated into a source driver 1143 which will be described below.

The memory 1120 may store various data used by at least one component (e.g., the processor 1110 or the sensor module 1161) of the electronic device 1000, and input or output data about a command associated with the various data. Also, various setting data corresponding to the setting of the user may be stored in the memory 1120. The memory 1120 may include at least one of the volatile memory 1121 and the nonvolatile memory 1122.

The input module 1130 may receive a command or data to be used in a component (e.g., the processor 1110, the sensor module 1161, or the sound output module 1163) of the electronic device 1000 from an outside (e.g., the user or the external electronic device 2000) of the electronic device 1000.

The input module 1130 may include a first input module 1131 to which a command or data is input from the user and a second input module 1132 to which a command or data is input from the external electronic device 2000. The first input module 1131 may include a microphone, a mouse, a keyboard, a key (e.g., a button), or a pen (e.g., a passive pen or an active pen). The second input module 1132 may support a specified protocol capable of connecting the electronic device 1000 to the external electronic device 2000 by wired or wireless communication. The second input module 1132 may include a high definition multimedia interface (HDMI), a universal serial bus (USB) interface, an SD card interface, or an audio interface. The second input module 1132 may include a connector, e.g., an HDMI connector, a USB connector, an SD card connector, or an audio connector (e.g., a headphone connector), which can physically connect the electronic device 1000 to the external electronic device 2000.

The display module 1140 may provide visual information to the user. The display module 1140 may include the display panel 1141, a gate driver 1142, the source driver 1143, and a voltage generating circuit 1144. The display module 1140 may further include a window for protecting the display panel 1141, a chassis, and a bracket. The display module 1140 may include at least some components of the display device 100 shown in FIG. 1.

The display panel 1141 may include a liquid crystal display panel, an organic light-emitting display panel, or an inorganic light-emitting display panel, and the kind of the display panel 1141 is not particularly limited. The display panel 1141 may be of a rigid type or a flexible type in which the display panel 1141 is rollable or foldable. The display module 1140 may further include a supporter for supporting the display panel 1141, a bracket, a heat dissipation member, or the like. The display panel 1141 may include the display panel 110 shown in FIG. 1.

The gate driver 1142 may be a driving chip, and may be mounted on the display panel 1141. The gate driver 1142 may be integrated in the display panel 1141. For example, the gate driver 1142 may include an Amorphous Silicon TFT Gate (ASG) driver circuit, a Low Temperature Polycrystalline Silicon (LTPS) TFT gate driver circuit, or an Oxide Semiconductor TFT Gate (OSG) driver circuit, which is embedded in the display panel 1141. The gate driver 1142 may receive a control signal from the controller 1112-1, and output scan signals to the display panel 1141 in response to the control signal. The gate driver 1142 may include the gate driver 120 shown in FIG. 1.

The display module 1140 may further include an emission driver. The emission driver may output an emission control signal to the display panel 1141 in response to a control signal received from the controller 1112-1. The emission driver may be formed separately from the gate driver 1142, or be integrated in the gate driver 1142. The emission driver may include the emission control driver 130 shown in FIG. 1.

The source driver 1143 may receive a control signal from the controller 1112-1, and convert image data into an analog voltage (e.g., a data voltage) and output data voltages to the display panel 1141 in response to the control signal. The source driver 1143 may include the data driver 140 shown in FIG. 1.

The source driver 1143 may be integrated in another component (e.g., the controller 1112-1). Functions of the interface conversion circuit and the timing control circuit of the controller 1112-1, which are described above, may be integrated in the source driver 1143.

The voltage generating circuit 1144 may output various voltages for driving the display panel 1141.

The source driver 1143 may convert data corresponding to red, green, and blue, included in image data received from the processor 110, into a red data signal, a green data signal, and a blue data signal, and provide the red data signal, the green data signal, and the blue data signal to multiple pixel columns included in the display panel 1141 during one horizontal period.

The power module 1150 may supply power to at least one component of the electronic device 1000. The power module 1150 may include a battery for charging a power voltage. The battery may include a primary cell which is not rechargeable, a secondary cell which is rechargeable, or a fuel cell. The power module 1150 may include a power management integrated circuit (PMIC). The PMIC may supply an optimized power to each of the above-described modules and modules which will be described below. The power module 1150 may include a wireless power transmission/reception member electrically connected to the battery. The wireless power transmission/reception member may include multiple coil-shaped antenna radiators. At least some components of the power module 1150 and the voltage generating circuit 1144 may be integral with each other. The voltage generating circuit 1144 may be included in the power module 1150.

The electronic device 1000 may further include the internal module 1160 and the external module 1170. The internal module 1160 may include the sensor module 1161, the antenna module 1162, and the sound output module 1163. The external module 1170 may include the camera module 1171, a light module 1172, and the communication module 1173.

The sensor module 1161 may sense an input caused by a body of the user or an input caused by a pen in the first input module, and generate an electrical signal or a data value, which corresponds to the input. The sensor module 1161 may include at least one of the fingerprint sensor 1161-1, the input sensor 1161-2, and a digitizer 1161-3.

The fingerprint sensor 1161-1 may generate a data value corresponding to a fingerprint of the user.

The input sensor 1161-2 may generate a data value corresponding to coordinate information of the input caused by the body of the user or the input caused by the pen. The input sensor 1161-2 may generate, as a data value, a capacitance variation caused by the input. The input sensor 1161-2 may sense an input caused by a passive pen, or transmit/receive data to/from an active pen.

The input sensor 1161-2 may measure a biometric signal such as pressure, moisture, or body fat. For example, in case that the user does not move for a constant time while a body part of the user is in contact with a sensor layer or a sensing panel, the input sensor 1161-2 may output information which the user wants to the display module 1140 by sensing a biometric signal, based on a change in electric field, caused by the body part.

The digitizer 1161-3 may generate a data value corresponding to the coordinate information of the input caused by the pen. The digitizer 1161-3 may generate, as a data value, an electromagnetic variation caused by the input. The digitizer 1161-3 may sense an input caused by the passive pen, or transmit/receive data to/from the active pen.

At least one of the fingerprint sensor 1161-1, the input sensor 1161-2, and the digitizer 1161-3 may be implemented as a sensor layer formed on the display panel 1141 through a continuous process. At least one of the fingerprint sensor 1161-1, the input sensor 1161-2, and the digitizer 1161-3 may be located at an upper side of the display panel 1141, and any one, e.g., the digitizer 1161-3, of the fingerprint sensor 1161-1, the input sensor 1161-2, and the digitizer 1161-3 may be located at a lower side of the display panel 1141.

At least two of the fingerprint sensor 1161-1, the input sensor 1161-2, and the digitizer 1161-3 may be formed to be integrated into one sensing panel through a same process. In case that at least two of the fingerprint sensor 1161-1, the input sensor 1161-2, and the digitizer 1161-3 are integrated into one sensing panel, the sensing panel may be located between the display panel 1141 and the window located at an upper side of the display panel 1141. In accordance with an embodiment, the sensing panel may be located on the window, and the position of the sensing panel is not particularly limited.

At least one of the fingerprint sensor 1161-1, the input sensor 1161-2, and the digitizer 1161-3 may be built in the display panel 1141. For example, at least one of the fingerprint sensor 1161-1, the input sensor 1161-2, and the digitizer 1161-3 may be simultaneously formed through a process of forming elements (e.g., a light-emitting element, a transistor, and the like) included in the display panel 1141.

The sensor module 1161 may generate an electrical signal or a data value, which corresponds to an internal state or an external state of the electronic device 1000. The sensor module 1161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1162 may include one or more antennas for transmitting a signal or power to the outside or receiving a signal or power from the outside. In accordance with an embodiment, the communication module 1173 may transmit a signal to the external electronic device or receive a signal from the external electronic device through an antenna suitable for a communication scheme. An antenna pattern of the antenna module 1162 may be integrated in one component (e.g., the display panel 1141) of the display module 1140, the input sensor 1161-2, or the like.

The sound output module 1163 may be a device for outputting a sound signal to the outside of the electronic device 1000, and include, for example, a speaker used for a general purpose such as multimedia playback or transcription playback and a receiver used for only call reception. The receiver may be integrally formed with the speaker or be formed separately from the speaker. A sound output pattern of the sound output module 1163 may be integrated in the display module 1140.

The camera module 1171 may photograph a still image and a moving image. The camera module 1171 may include one or more lenses, an image sensor, or an image signal processor. The camera module 1171 may further include an infrared camera capable of measuring existence of the user, a position of the user, eyes of the user, or the like.

The light module 1172 may provide light. The light module 1172 may include a light-emitting diode or a xenon lamp. The light module 1172 may operate in linkage with the camera module 1171 or operate independently from the camera module 1171.

The communication module 1173 may establish a wired or wireless communication channel between the electronic device 1000 and the external electronic device 2000, and support communication performance through the established communication channel. The communication module may include one or all of a wireless communication module such as a cellular communication module, a short-range wireless communication module, or a global navigation satellite system (GNSS) communication module, and a wired communication module such as a local area network (LAN) communication module or a power line communication (PLC) module. The communication module 1173 may communicate with the external electronic device 2000 through a short-range communication network such as Bluetooth™, wireless-fidelity (WiFi) direct, or infrared data association (IrDA), or a long-range communication network such as a cellular network, Internet, or a computer network (e.g., LAN or wide area network (WAN)). The above-described communication modules may be implemented into one chip or be respectively implemented as separate chips.

The input module 1130, the sensor module 1161, the camera module 1171, and the like may be used to control an operation of the display module 1140 in linkage with the processor 1110.

The processor 1110 may output a command or data to the display module 1140, the sound output module 1163, the camera module 1171, or the light module 1172, based on input data received from the input module 1130. For example, the processor 1110 may generate image data, corresponding to input data applied through a mouse, an active pen, or the like, and output the image data to the display module 1140. For example, the processor 1110 may generate command data, corresponding to the input data, and output the command data to the camera module 1171 or the light module 1172. In case that no input data is received from the input module 1130, the processor 1110 may change the operation mode of the electronic device 1000 to a low power mode or a sleep mode, thereby reducing power consumed in the electronic device 1000.

The processor 1110 may output a command or data to the display module 1140, the sound output module 1163, the camera module 1171, or the light module 1172, based on sensing data received from the sensor module 1161. For example, the processor 1110 may compare authentication data applied by the fingerprint sensor 1161-1 with authentication data stored in the memory 1120, and execute an application according to a comparison result. The processor 1110 may execute a command or output corresponding image data to the display module 1140, based on sensing data sensed by the input sensor 1161-2 or the digitizer 1161-3. In case that a temperature sensor is included in the sensor module 1161, the processor 1110 may receive temperature data about a temperature measured from the sensor module 1161, and further perform luminance correction on image data, based on the temperature data.

The processor 1110 may receive measurement data about appearance of the user, a position of the user, eyes of the user, or the like from the camera module 1171. The processor 1110 may further perform luminance correction on image data, based on the measurement data. For example, the process 1110 which decides the appearance of the user through an input from the camera module 1171 may output image data of which luminance is corrected to the display module 1140 through the data conversion circuit 1112-2 or the gamma correction circuit 1112-3.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first-first gate line comprising a first-first-fist gate line, a first-first-second gate line, and a first bridge line connecting the first-first-first gate line and the first-first-second gate line to each other, the first-first gate line extending in a first direction; and
a first-second gate line comprising a first-second-first gate line, a first-second-second gate line, and a second bridge line connecting the first-second-first gate line and the first-second-second gate line to each other, the first-second gate line being spaced apart from the first-first gate line in a second direction intersecting the first direction, the first-second gate line extending in the first direction,
wherein a first contact hole connecting the first-first-first gate line and the first bridge line to each other is located between the first-first-first gate line and the first-second-second gate line.

2. The display device of claim 1, wherein a second contact hole connecting the first-second-first gate line and the second bridge line to each other is spaced apart from the first contact hole in the first direction, and is located between the first-first-second gate line and the first-second-second gate line.

3. The display device of claim 2, wherein the first bridge line extends to overlap at least a portion of the first-first-second gate line in a plan view.

4. The display device of claim 3, wherein the second bridge line extends to overlap at least a portion of the first-second-second gate line in a plan view.

5. The display device of claim 2, further comprising:
a first data line connected to a pair of first sub-pixels;
a second data line connected to a pair of second sub-pixels; and
a third data line connected to a pair of third sub-pixels.

6. The display device of claim 5, wherein
the pair of first sub-pixels are symmetrical to each other with respect to the first data line,
the pair of second sub-pixels are symmetrical to each other with respect to the second data line, and
the pair of third sub-pixels are symmetrical to each other with respect to the third data line.

7. The display device of claim 6, wherein
the first-first gate line is connected to one of the pair of first sub-pixels, one of the pair of second sub-pixels, and one of the pair of third sub-pixels, and
the first-second gate line is connected to another one of the pair of first sub-pixels, another one of the pair of second sub-pixels, and another one of the pair of third sub-pixels.

8. The display device of claim 7, wherein the first contact hole is located between the another one of the pair of first sub-pixels and the one of the pair of second sub-pixels.

9. The display device of claim 8, wherein the second contact hole is located between the another one of the pair of second sub-pixels and the one of the pair of third sub-pixels.

10. The display device of claim 9, wherein the first contact hole and the second contact hole are repeatedly arranged in each sub-pixel unit comprising the pair of first sub-pixels, the pair of second sub-pixels, and the pair of third sub-pixels.

11. A display device comprising:
a first-first-first gate line and a first-second-first gate line, which are located on a substrate;
a buffer layer covering the first-first-first gate line and the first-second-first gate line;
a first gate insulating layer and a second gate insulating layer, which are located on the buffer layer;
a first-first-second gate line located on the first gate insulating layer and a first-second-second gate line located on the second gate insulating layer;
an interlayer insulating layer covering the first-first-second gate line and the first-second-second gate line; and
a first bridge line and a second bridge line, which are located on the interlayer insulating layer, wherein
the first bridge line is connected to the first-first-first gate line through a first contact hole,
the second bridge line is connected to the first-second-first gate line through a second contact hole, and
the first contact hole is located between the first-first-second gate line and the first-second-second gate line.

12. The display device of claim 11, wherein the second contact hole is spaced apart from the first contact hole in a first direction, and is located between the first-first-second gate line and the first-second-second gate line.

13. The display device of claim 12, wherein the first bridge line extends to overlap at least a portion of the first-first-second gate line in a plan view.

14. The display device of claim 13, wherein the second bridge line extends to overlap at least a portion of the first-second-second gate line in a plan view.

15. The display device of claim 11, further comprising:
a first data line connected to a pair of first sub-pixels;
a second data line connected to a pair of second sub-pixels; and
a third data line connected to a pair of third sub-pixels.

16. The display device of claim 15, wherein
the pair of first sub-pixels are symmetrical to each other with respect to the first data line,
the pair of second sub-pixels are symmetrical to each other with respect to the second data line, and
the pair of third sub-pixels are symmetrical to each other with respect to the third data line.

17. The display device of claim 16, wherein
the first-first-first gate line and the first-first-second gate lines are connected to one of the pair of first sub-pixels, one of the pair of second sub-pixels, and one of the pair of third sub-pixels, and
the first-second-first gate line and the first-second-second gate line are connected to another one of the pair of first sub-pixels, another one of the pair of second sub-pixels, and another one of the pair of third sub-pixels.

18. The display device of claim 17, wherein the first contact hole is located between the another one of the pair of first sub-pixels and the one of the pair of second sub-pixels.

19. The display device of claim 18, wherein
the second contact hole is located between the another one of the pair of second sub-pixels and the one of the pair of third sub-pixels, and
the first contact hole and the second contact hole are repeatedly arranged in each sub-pixel unit comprising the pair of first sub-pixels, the pair of second sub-pixels, and the pair of third sub-pixels.

20. An electronic device comprising:
a display device; and
a processor that drives the display device, wherein
the display device includes:
a first-first gate line comprising a first-first-first gate line, a first-first-second gate line, and a first bridge line connecting the first-first-first gate line and the first-first-second gate line to each other, the first-first gate line extending in a first direction; and
a first-second gate line comprising a first-second-first gate line, a first-second-second gate line, and a second bridge line connecting the first-second-first gate line and the first-second-second gate line to each other, the first-second gate line being spaced apart from the first-first gate line in a second direction intersecting the first direction, the first-second gate line extending in the first direction, and
a first contact hole connecting the first-first-first gate line and the first bridge line to each other is located between the first-first-second gate line and the first-second-second gate line.
